(19) United States
(12) Patent Application Publication
(10) Pub. No.: US 2025/0002061 A1
(43) Pub. Date: Jan. 2, 2025

(54) SAFE CODING METHOD FOR TRACKSIDE TRAIN POSITIONING INFORMATION

(71) Applicant: CASCO SIGNAL LTD., Jing'an District, Shanghai (CN)

(72) Inventors: Cheng ZHANG, Jing'an District, Shanghai (CN); Jiyu CHEN, Jing'an District, Shanghai (CN); Weijuan LI, Jing'an District, Shanghai (CN); Zhijun JI, Jing'an District, Shanghai (CN); Liang CHEN, Jing'an District, Shanghai (CN); Li BAO, Jing'an District, Shanghai (CN); Yingchun ZHU, Jing'an District, Shanghai (CN); Hongguang HE, Jing'an District, Shanghai (CN)

(21) Appl. No.: 18/708,836

(22) PCT Filed: Nov. 9, 2022
(86) PCT No.: PCT/CN2022/130879

§ 371 Date: May 9, 2024

(30) Foreign Application Priority Data
Sep. 1, 2022 (CN) 202211068446.9

(51) Int. Cl. B61L 25/02; G06T 7/70

(52) U.S. Cl. CPC B61L 25/025; G06T 7/70; G06T 2207/10016

(57) ABSTRACT

A safe coding method for trackside train positioning information, including the following steps: compiling line position coding information of a train by using a redundancy coding scheme; identifying a coding string on a trackside signboard by an image collector, and sending the coding string to a vehicle-mounted safety computer after check; after performing multi-channel redundancy safe calculation on the coding string by the vehicle-mounted safety computer, looking up a table in a position database to obtain train position information corresponding to the coding string; and, updating a real position of the train according to the train position information determined by looking up the table. The method integrates redundancy, inverse check calculation and other means, thereby improving the safety of position calculation, remedying the reliability and safety defects of visual identification, and improving the positioning accuracy of passive train positioning based on a trackside device by an image collection technology.

### TECHNICAL FIELD

The present invention relates to the field of train positioning, and in particular to a safe coding method for trackside train positioning information.

### BACKGROUND

In a rail traffic signal system, a train positioning technology is extremely critical. Only with sufficiently accurate train positioning, the state of the train can be accurately controlled to ensure the travel safety. At present, there are many train positioning technologies, including vehicle-mounted based active positioning, such as a coding odometer train positioning technology and a millimeter-wave radar technology, and trackside device-based passive positioning, such as image collection positioning. When an image collection technology is used for positioning, the coding reliability and check scheme of a graph is particularly important. Therefore, a safe and reliable safe coding technology is required to improve the accuracy and safety of image collection positioning, thereby improving the positioning precision and positioning safety of the train.

### SUMMARY

An objective of the present invention is to design a safe and reliable safe coding technology to improve the positioning accuracy and safety during trackside device-based passive train positioning by an image collection technology.

To achieve the objective, the present invention provides a safe coding method for trackside train positioning information, including the following steps:
S1: compiling line position coding information of a train by using a redundancy coding scheme to form a position coding string;
S2: printing the position coding string compiled in Step S1 and including the line position coding information into a signboard, and mounting the signboard on a trackside sleeper;
S3: mounting an image collector on a train body, collecting a coding string on the signboard by the image collector, preliminarily checking the coding string, and sending the identified coding string to a vehicle-mounted safety computer after passing the check;
S4: receiving, by the vehicle-mounted safety computer, the coding string sent by the image collector, performing multi-channel redundancy safe calculation on the coding string, and looking up a table in a position database to obtain train position information corresponding to the coding string; and
S5: updating a real position of the train according to the train position information determined by looking up the table in S4.

The position coding string includes four parts, namely a head code identification area, a first part code area, a second part code area and a third part code area, respectively configured to identify a code, represent position information, verify the position information and perform redundancy check.

The head code identification area is a fixed code, and the head code identification area is an identifier of the position coding string and configured to confirm that the coding string is the line position coding information.

The first part code area adopts a positive 32-bit code, denoted as N, and the first part code area represents the position information of the train.

The second part code area is an inverse code of the first part code area, denoted as M, M=N; and the third part code area is a cyclic redundancy check code of the first part coding area, denoted as P, P=CRC32(N).

After identification coding information is collected subsequently, whether the second part coding area of the collected coding string is the inverse code of N and whether the third part coding area is the cyclic redundancy check code of N are checked so as to determine whether the collected coding string is a coding string including the train position information.

The image collector includes a video sensor and an identification check module; the video sensor is capable of collecting a coding string represented by a graph on the trackside signboard; and the identification check module is capable of identifying and preliminarily checking the coding string represented by the graph.

Step S3 further includes the following steps:
S31: collecting, by the image collector, the coding string represented by the graph on the trackside signboard through the video sensor, identifying and searching for a head code identification area by the identification check module, determining whether a code of the head code area is a set fixed code, continuing a next step if the code of the head code area is the set fixed code, and identifying and searching for a next group of graphs if the code of the head code area is not the set fixed code;
S32: identifying and recording information N of the first part code area of the coding string by the identification check module;
S33: identifying and recording information M of the second part code area of the coding string by the identification check module;
S34: determining, by the identification check module, whether M is the inverse code of N, returning to S31 to identify the next group of graphs if M is not the inverse code of N, and continuing a next step if M is the inverse code of N;
S35: identifying and recording information P of the third part code area of the coding string by the identification check module;
S36: determining, by the identification check module, whether P is the cyclic redundancy check code of N, passing the preliminary check if P is equal to the cyclic redundancy check code of N and performing the next step, and returning to S31 to identify the next group of graphs if P is not equal to the cyclic redundancy check code of N; and
S37: sending, by the image collector, the coding string Sn (N, M, P) to the vehicle-mounted safety computer.

Step S4 further includes the following steps:
S41: performing safe calculation check on the coding string Sn (N, M, P) by each of a plurality of channels included in the vehicle-mounted safety computer, and searching for corresponding train position information in the position database; and
S42: comparing whether train position information corresponding to the coding string Sn (N, M, P) found by the safe calculation check of each of the channels is completely consistent, if the train position information is completely consistent, determining that the train position information is the final reliable train position information obtained through image positioning, and if the train position information is not completely consistent, returning to Step S3.

For each of the channels of the vehicle-mounted safety computer, Step S41 is performed, and Step S41 further includes the following steps:
S411: determining whether N is equal to −M, if N is not equal to −M, discarding the group of coding string data, exiting this calculation and returning to Step S3, and if N is equal to −M, continuing a next step;
S412: determining whether P is equal to CRC32(N), if P is equal to CRC32(N), determining that the coding string Sn (N, M, P) passes the safe calculation check of the channel and continuing a next step, and if P is not equal to CRC32(N), returning to Step S3; and
S413: according to the coding string Sn (N, M, P), performing search in the stored train position database, and determining the train position information S.

A corresponding relationship between all the coding strings on the line and the train position information is stored in the train position database; and after the line is changed, the position database is correspondingly adjusted.

Step S5 further includes the following steps:
S51: assuming that position information of the train at time T0 is S0, at time T1, determining first position information Sa of the train at the time T1 by a train self-positioning method in combination with S0, calculating second position information Sx of the train at the time T1 by using Steps S3-S4, at time T2, determining third position information Sb of the train at the time T2 by the train self-positioning method in combination with S0, and calculating fourth position information Sy of the train at the time T2 by using Steps S3-S4; and
S52: determining whether the first position information Sa, the second position information Sx, the third position information Sb and the fourth position information Sy meet constraint conditions, where the constraint conditions are:

T0<T1<T2 and T2−T0<60S,

|Sy−Sx|≥0 and |Sx−S0|≥0,

∥Sy−Sx|−|Sa−Sb∥<0.5,

if all the constraint conditions are met, correcting the positioning information of the train at the time T2 as Sy; and if not all the constraint conditions are met, operating Steps S3 to S5 again until the constraint conditions are met.

When the train has just started, the positions of a plurality of parts of a train body are required to be calculated and verified, including the following steps: determining position information of more than four parts of the train body at the same time by using the image collection and identification process in Steps S3 and S4 and the vehicle-mounted safety computer processing process; and if the sequence of the position information of the selected parts is consistent with the sequence of the actual position of the selected parts, and a position difference between any two parts is less than a length of the train, indicating that the train position information obtained by Steps S3 and S4 of this method is reliable, and performing S5 to update the actual position of the train.

Compared with the prior art, the present invention has the following beneficial effects:

1. Safe check used in this method does not depend on the image collector, thereby reducing the safety requirement on the image collector.

2. In this method, preliminary data validity calculation is performed by the image collector, the checked data is sent to the vehicle-mounted safety computer, and the image collector cannot truly calculate and count the position information of the train.

3. In this method, the information of the image collector received by the vehicle-mounted safety computer is subjected to safety calculation of three parts of coding information, and after calculation is passed, the position information of the train can be obtained by matching the position database; the position database can perform adjustment timely according to the change of the line, so that the trackside replacement can be avoided, and the maintenance cost of the system can be reduced; and the scheme is in low implementation cost and relatively simple in maintenance.

4. According to the method, the safety of position calculation can be improved by position coding, multi-channel image collection redundancy, inverse check calculation and other means, thereby remedying the reliability and safety defects of visual identification,

### BRIEF DESCRIPTION OF DRAWINGS

FIG. 1 is a schematic diagram of steps of a safe coding method for trackside train positioning information according to the present invention;

FIG. 2 is a schematic diagram of line position coding information of a safe coding method for trackside train positioning information according to the present invention; and

FIG. 3 is an identification flowchart of an image collector in a safe coding method for trackside train positioning information according to the present invention.

### DESCRIPTION OF THE EMBODIMENTS

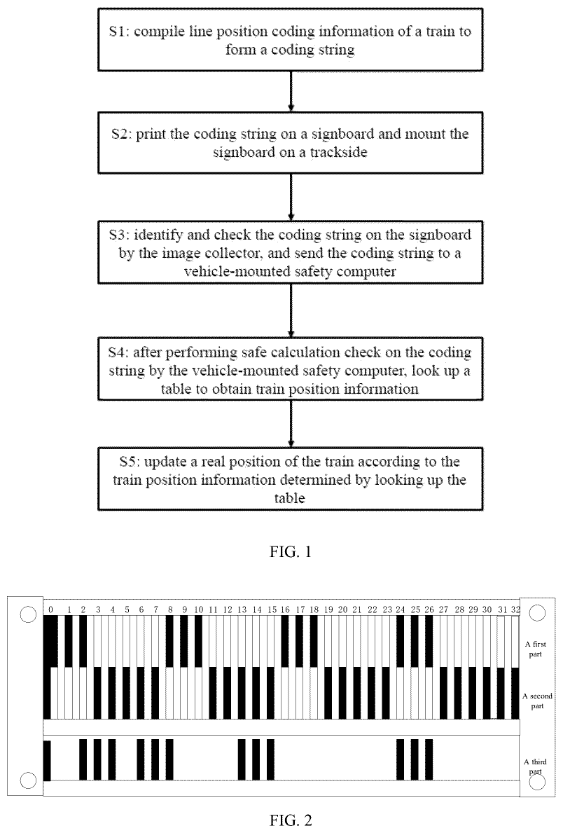

The technical solutions, structural features, structural characteristics, achieved objectives and effects in embodiments of the present invention are described below in detail with reference to FIG. 1 to FIG. 3 in the embodiments of the present invention.

It should be noted that the accompanying drawings adopt a very simplified form and all use inaccurate proportions, which are only used to assist in describing the implementation of the present invention conveniently and clearly and are not intended to limit the implementation conditions of the present invention. Therefore, it has no technical substantive significance. Any structural modification, change of a scale relationship or adjustment of size should still fall within the scope which can be covered by the technical content disclosed by the present invention without affecting the effects and the objective achieved by the present invention.

It should be noted that in this specification, relational terms such as first and second are only used to differentiate one entity or operation from another entity or operation, and do not necessarily require or imply that any actual relation or sequence exists between these entities or operations. Besides, the terms “comprise”, “include” or any other variants thereof are intended to cover non-exclusive inclusion, so that a process, method, article or device including a series of elements not only includes elements explicitly listed, but further includes other elements not explicitly listed, or also includes elements inherent to such process, method, article or device.

According to a safe coding method for trackside train positioning information, line position information is coded, a coded graph is placed at a trackside for a train device to collect and identify, thereby determining the position of the train. As shown in FIG. 1, the method includes the following steps:

S1: line position coding information is compiled by using a redundancy coding scheme.

Coding the line position is a technical key for train safety positioning. According to the present invention, black and white stripes are used to compile line position coding information to form a position coding string, that is, a graph shown in FIG. 2. It is specified that the black stripes represent 1 information, and the white stripes represent 0 information.

The position coding string includes four parts, as shown in FIG. 2, sequentially a head code identification area (not shown in the figure), a first part code area, a second part code area and a third part code area, respectively configured to identify a code, represent position information, verify the position information and perform redundancy check.

The head code identification area is a fixed code, including three parts, sequentially a fixed code 11, a fixed code 10 and a fixed code 10. The head code identification area is an identifier of the position coding string and configured to confirm that the position coding string represents the line position coding information.

The first part code area adopts a positive 32-bit code, denoted as N. Since the 32^{nd} power of 2 is 4294967296, if the positioning precision is a centimeter level, the line position is coded by the positive 32-bit code, the positioning requirement of 40000-km railway line mileage can be met theoretically, which is enough for rail traffic system of a city. It should be noted that in principle, the first part code area does not represent the mileage information of the line, but only serves as position information.

The second part code area adopts an inverse code of the first part code area, denoted as M, for checking the coding information. Specifically, M=−N. The third part code area is a cyclic redundancy check code P of the first part code area, specifically, P=CRC32(N).

After the coding information is collected and identified subsequently, whether the second part code area of the collected coding string is the inverse code of N and whether the third part code area is the cyclic redundancy check code of N are checked so as to determine whether the collected coding string is a coding string including the train position information, thereby improving the train positioning efficiency based on image identification.

S2: the position coding string compiled in Step S1 and including the line position coding information is printed into a signboard, and the signboard is mounted on a trackside sleeper.

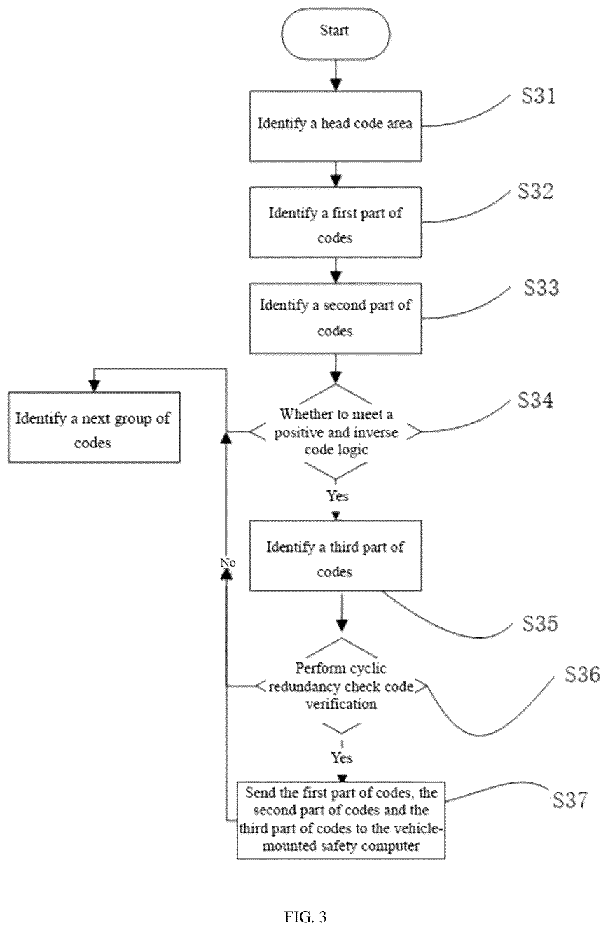

S3: an image collector is mounted on a train body. The image collector includes a video sensor and an internal identification check module. The video sensor can collect a graph on a trackside signboard. The identification check module can identify and preliminarily the coding string represented by the graph. As shown in FIG. 3, Step S3 specifically includes the following steps:

S31: the image collector collects the graph, that is, the coding string, on the trackside signboard through the video sensor; a head code identification area of the coding string is identified and searched by the identification check module; after the head code identification area is found, it is determined whether the code of the head code area is 111010; if the code is 111010, a next step is continued; and if the code is not 111010, a next group of graphs are continuously identified and searched.

S32: the identification check module of the image collector identifies and records information N of the first part code area of the coding string.

S33: the identification check module of the image collector identifies and records information M of the second part code area of the coding string.

S34: the identification check module of the image collector determines whether M is the inverse code of N, that is, whether M is equal to −N; if M is not the inverse code of N, it means that the coding string is not line position coding information and graph identification is wrong, and it is necessary to return to S31 to identify a next group of graphs; and if M is the inverse code of N, a next step is continued.

S35: the identification check module of the image collector identifies and records information P of the third part code area of the coding string.

S36: the identification check module of the image collector determines whether P is the cyclic redundancy check code of N, that is, whether P is equal to CRC32(N); if P is equal to CRC32(N), preliminary check is passed, and the coding string represented by the graph on the signboard is line position coding information, and a next step is continued; and if P is not equal to CRC32(N), S31 is returned to identify a next group of graphs.

S37: the image collector sends the identified and recorded coding string Sn (N, M, P) to the vehicle-mounted safety computer for the vehicle-mounted safety computer to determine the train position information.

S4: the vehicle-mounted safety computer receives the coding string Sn(N, M, P) sent by the image collector, redundancy safe calculation is performed on the Sn(N, M, P), and the train position information in the position database is obtained by looking up a table.

S41: to ensure the train positioning correctness of the train through image identification, double channels are arranged in the vehicle-mounted safety computer, namely a first channel and a second channel, and the coding string Sn(N, M, P) is subjected to safe calculation check of the double channels. For each of the channels, S41 further includes the following steps:

S411: it is determined whether N is equal to −M, if N is not equal to −M, the group of coding string is discarded, this calculation is exited and Step S3 is returned, and if N is equal to −M, a next step is continued.

S412: it is determined whether P is equal to CRC32(N), if P is equal to CRC32(N), the coding string Sn (N, M, P) passes the safe calculation check of the channel and if P is not equal to CRC32(N), Step S3 is returned, and a next graph is continuously identified.

S413: according to the coding string Sn (N, M, P), search is performed in the stored train position database, and the train position information S is determined.

A corresponding relationship between all the coding strings on the line and the train position information is stored in the train position database. Therefore, the train position information can be determined according to the coding string. After the line is replaced, the position database can be adjusted timely and correspondingly, thereby avoiding the replacement of the trackside signboard.

The process of Steps S411-S413 may adopt the following codes:

```
Chenck_Loc(N, M, P)
{
  if ( N==−M)
  { if (P=CRC32 (N)
      return N
    return ERROR
    }
    else
return ERROR
}
Car_Loc(N, M, P)
  {
  TEMP =Chenck_Loc(N, M, P)
  Return Seach_Map(TEMP)
}
S=Car_Loc(N, M, P)
```

S42: S41 is performed for each channel, and the train position information S found by the first channel and the second channel is compared; if the train position information S is completely consistent, the train position information S is the final reliable train position information obtained through image positioning; and if the train position information S is not completely consistent, Step S3 is returned, and a next group of graphs are identified and checked.

It should be noted that the first channel and the second channel are arranged in the vehicle-mounted safety computer used in this embodiment, but more channels may be provided, so that the result is more reliable.

S5: a real position of the train is updated according to the train position information S determined in S4.

To ensure the reliability and safety of train positioning, it is particularly critical to obtain the initial position information of the train. Therefore, before the real position of the train is updated by the method, it is necessary to use the method to calculate and verify the positions of a plurality of parts of the train body when the train has just started.

Specifically, more than four parts of the train body are selected, and the position information of these parts are determined at the same time by using the image collection and identification process and the vehicle-mounted safety computer processing process in Steps S3 and S4; and if the sequence of the position information of the selected parts is consistent with the sequence of the actual position of the selected parts, and a position difference between any two parts is less than a length of the train, it means that the train position information obtained by Steps S1-S4 is reliable, and the actual position of the train can be updated by this method.

For example, according to the driving direction or the reverse direction of the train, two parts of the tail of the train and two parts of the head of the train are selected sequentially, and four pieces of position information, sequentially S1, S2, S3 and S4, are obtained after Steps S3 and S4; and the train position information is determined, if S1<S2<S3<S4 or S4<S3<S2<S1, |S3−S1|≥Lₜᵣₐᵢₙ and |S4−S2|≥Lₜᵣₐᵢₙ are met, it means that the train position information at this time is reliable.

The step of updating the real position of the train is specifically as follows:

S51: assuming that the position information of the train at time T0 is S0, S0 is the train position information after continuous correction.

At time T1, first position information Sa of the train at the time T1 is determined in combination with a radar, a coding odometer and other parts, a common train self-positioning method in the prior art and S₀; and second position information Sx of the train at the time T1 is calculated by using Steps S3-S4.

At time T2, third position information Sb of the train at the time T2 is determined in combination with a radar, a coding odometer and other parts, the common train self-positioning method in the prior art and S₀; and fourth position information Sy of the train at the time T2 is calculated by using Steps S3-S4.

S52: it is determined whether the first position information Sa, the second position information Sx, the third position information Sb and the fourth position information Sy meet constraint conditions. The constraint conditions are:

T0<T1<T2 and T2−T0<60S; 1)

|Sy−Sx|≥0 and |Sx−S₀|≥0; and 2)

∥Sy−Sx|−|S⁺a-Sb∥<0.5. 3)

If the first position information Sa, the second position information Sx, the third position information Sb and the fourth position information Sy meet the constraint conditions, the positioning information of the train at the time T2 is modified as Sy; and if not all the constraint conditions are met, the second position information Sx and the fourth position information Sy are discarded, Steps S3 to S5 are operated again until the constraint conditions are met.

In the running process of the train, S51−S52 are continuously used to correct the train self-positioning position Sb, thereby continuously improving the train positioning precision.

Although the content of the present invention has been described in detail through the aforementioned preferred embodiments, it should be recognized that the above description should not be considered as limiting the present invention. Various modifications and alternatives to the present invention will become apparent to those skilled in the art upon reading the foregoing disclosure. Accordingly, the protection scope of the present invention shall be limited by the appended claims.

1. A safe coding method for trackside train positioning information, comprising the following steps:
S1: compiling line position coding information of a train by using a redundancy coding scheme to form a position coding string;
S2: printing the position coding string compiled in Step S1 and comprising the line position coding information into a signboard, and mounting the signboard on a trackside sleeper;
S3: mounting an image collector on a train body, collecting a coding string on the signboard by the image collector, preliminarily checking the coding string, and sending the identified coding string to a vehicle-mounted safety computer after passing the check;
S4: receiving, by the vehicle-mounted safety computer, the coding string sent by the image collector, performing multi-channel redundancy safe calculation on the coding string, and looking up a table in a position database to obtain train position information corresponding to the coding string; and
S5: updating a real position of the train according to the train position information determined by looking up the table in Step S4.

2. The safe coding method for trackside train positioning information according to claim 1, wherein the position coding string comprises four parts, namely a head code identification area, a first part code area, a second part code area and a third part code area, respectively configured to identify a code, represent position information, verify the position information and perform redundancy check.

3. The safe coding method for trackside train positioning information according to claim 2, wherein the head code identification area is a fixed code, and the head code identification area is an identifier of the position coding string and configured to confirm that the coding string is the line position coding information.

4. The safe coding method for trackside train positioning information according to claim 2, wherein the first part code area adopts a positive 32-bit code, denoted as N, and the first part code area represents the position information of the train.

5. The safe coding method for trackside train positioning information according to claim 4, wherein the second part code area is an inverse code of the first part code area, denoted as M, M=N; and the third part code area is a cyclic redundancy check code of the first part code area, denoted as P, P=CRC32(N).

6. The safe coding method for trackside train positioning information according to claim 4, wherein after identification coding information is collected subsequently, whether the second part code area of the collected coding string is the inverse code of N and whether the third part code area is the cyclic redundancy check code of N are checked so as to determine whether the collected coding string is a coding string comprising the train position information.

7. The safe coding method for trackside train positioning information according to claim 1, wherein the image collector comprises a video sensor and an identification check module; the video sensor is capable of collecting a coding string represented by a graph on the trackside signboard; and the identification check module is capable of identifying and preliminarily checking the coding string represented by the graph.

8. The safe coding method for trackside train positioning information according to claim 7, wherein Step S3 further comprises the following steps:
S31: collecting, by the image collector, the coding string represented by the graph on the trackside signboard through the video sensor, identifying and searching for a head code identification area by the identification check module, determining whether a code of the head code area is a set fixed code, continuing a next step if the code of the head code area is the set fixed code, and identifying and searching for a next group of graphs if the code of the head code area is not the set fixed code;
S32: identifying and recording information N of the first part code area of the coding string by the identification check module;
S33: identifying and recording information M of the second part code area of the coding string by the identification check module;
S34: determining, by the identification check module, whether M is the inverse code of N, returning to Step S31 to identify the next group of graphs if M is not the inverse code of N, and continuing a next step if M is the inverse code of N;
S35: identifying and recording information P of the third part code area of the coding string by the identification check module;
S36: determining, by the identification check module, whether P is the cyclic redundancy check code of N, passing the preliminary check if P is equal to the cyclic redundancy check code of N and performing the next step, and returning to Step S31 to identify the next group of graphs if P is not equal to the cyclic redundancy check code of N; and
S37: sending, by the image collector, the coding string Sn (N, M, P) to the vehicle-mounted safety computer.

9. The safe coding method for trackside train positioning information according to claim 8, wherein Step S4 further comprises the following steps:
S41: performing safe calculation check on the coding string Sn (N, M, P) by each of a plurality of channels comprised in the vehicle-mounted safety computer, and searching for corresponding train position information in the position database; and
S42: comparing whether train position information corresponding to the coding string Sn (N, M, P) found by the safe calculation check of each of the channels is completely consistent, if the train position information is completely consistent, determining that the train position information is the final reliable train position information obtained through image positioning, and if the train position information is not completely consistent, returning to Step S3.

10. The safe coding method for trackside train positioning information according to claim 9, wherein for each of the channels of the vehicle-mounted safety computer, Step S41 is performed, and Step S41 further comprises the following steps:
S411; determining whether N is equal to −M, if N is not equal to −M, discarding the group of coding string data, exiting this calculation and returning to Step S3, and if N is equal to −M, continuing a next step;
S412: determining whether P is equal to CRC32(N), if P is equal to CRC32(N), determining that the coding string Sn (N, M, P) passes the safe calculation check of the channel and continuing a next step, and if P is not equal to CRC32(N), returning to Step S3; and
S413: according to the coding string Sn (N, M, P), performing search in the stored train position database, and determining the train position information S.

11. The safe coding method for trackside train positioning information according to claim 10, wherein a corresponding relationship between all the coding strings on the line and the train position information is stored in the train position database; and after the line is changed, the position database is correspondingly adjusted.

12. The safe coding method for trackside train positioning information according to claim 10, wherein Step S5 further comprises the following steps:
S51: assuming that position information of the train at time T0 is S₀, at time T1, determining first position information Sa of the train at the time T1 by a train self-positioning method in combination with S₀, calculating second position information Sx of the train at the time T1 by using Steps S3 and S4, at time T2, determining third position information Sb of the train at the time T2 by the train self-positioning method in combination with S₀, and calculating fourth position information Sy of the train at the time T2 by using Steps S3 and S4; and
S52: determining whether the first position information Sa, the second position information Sx, the third position information Sb and the fourth position information Sy meet constraint conditions, wherein the constraint conditions are:
T0<T1<T2 and T2−T0<60 seconds,

|Sy−Sx|≥0 and |Sx−S0|≥0,
∥Sy−Sx|−|Sa−Sb∥|<0.5,
if all the constraint conditions are met, correcting the positioning information of the train at the time T2 as Sy; and if not all the constraint conditions are met, operating Steps S3 to S5 again until the constraint conditions are met.

13. The safe coding method for trackside train positioning information according to claim 12, wherein when the train has just started, the positions of a plurality of parts of the train body are required to be calculated and verified, comprising the following steps: determining position information of more than four parts of the train body at the same time by using the image collection and identification process in Steps S3 and S4 and the vehicle-mounted safety computer processing process; and if the sequence of the position information of the selected parts is consistent with the sequence of the actual position of the selected parts, and a position difference between any two parts is less than a length of the train, indicating that the train position information obtained by Steps S3 and S4 of the method is reliable, and performing Step S5 to update the actual position of the train.
